(19) United States
(12) Patent Application Publication
(10) Pub. No.: US 2024/0077868 A1
(43) Pub. Date: Mar. 7, 2024

(54) CONFIGURABLE MULTI-SENSOR INPUT

(71) Applicant: Schweitzer Engineering Laboratories, Inc., Pullman, WA (US)

(72) Inventors: Veselin Skendzic, Schwenksville, PA (US); Travis C. Mallett, Pullman, WA (US); Syed Ali Kazi, Pullman, WA (US); Harshad S. Aherao, Chester Springs, PA (US); Dhruba P. Das, Coatesville, PA (US); Sandesh Chitnis, Pullman, WA (US)

(73) Assignee: Schweitzer Engineering Laboratories, Inc., Pullman, WA (US)

(21) Appl. No.: 17/930,251

(22) Filed: Sep. 7, 2022

(51) Int. Cl. G05B 23/02; G01R 15/18; G06F 1/26; G06F 13/42; H03M 1/12

(52) U.S. Cl. CPC G05B 23/0283; G01R 15/181; G06F 1/266; G06F 13/4221; H03M 1/123

(57) ABSTRACT

A configurable multi-sensor analog input may be utilized to connect a power system sensor to an intelligent electronic device. The configurable multi-sensor analog input may include an input port comprising a plurality of input pins and configured to receive electrical signals from one of a plurality of types of power system sensors. The configurable multi-sensor analog input may additionally include a plurality of input channels, each of the plurality of input channels coupled to a subset of the input pins, wherein the subset of input pins in electrical communication with of the plurality of types of power system sensors power system sensor is configured to selectively activate one of the plurality of input channels. A multiplexer may be in electrical communication with the plurality of input channels and configured to select an output based on the subset of input pins in electrical communication with one of the plurality of types of power system sensors.

### TECHNICAL FIELD

This disclosure relates to systems, devices, and methods for multi-sensor inputs for intelligent electronic devices. More particularly, but not exclusively, this disclosure relates to inputs for intelligent electronic devices (“IEDs”) that are capable of interfacing with multiple types of power system sensors, such as low energy analog (LEA) sensors, compatible with International Electrotechnical Commission (“IEC”) standard 61869.

### BRIEF DESCRIPTION OF THE DRAWINGS

Non-limiting and non-exhaustive embodiments of the disclosure are described, including various embodiments of the disclosure with reference to the figures, in which:

FIG. 1 is a one-line diagram of an electric power delivery system having an IED that includes inputs configured to couple to multiple sensor types, in accordance with embodiments of the present disclosure.

FIG. 2 is a simplified block diagram of the intelligent electronic device of FIG. 1.

FIG. 3 is a simplified block diagram of an input of the intelligent electronic device of FIG. 1.

FIG. 4 is a schematic diagram of a portion of the input circuitry for the input of FIG. 3.

### DETAILED DESCRIPTION

Electric power systems are used to generate, transmit, and distribute electric power to loads and serve as an important part of critical infrastructure. Electric power systems include equipment, such as generators, transmission and distribution lines, transformers, capacitor banks, and electrical substations, to provide electrical energy from sources to loads. In some cases, electric power systems and equipment may be monitored and protected by a variety of types of equipment. Such equipment may include sensors to monitor currents, voltages, phases, and other parameters of the electric power system. Such equipment may additionally include circuit breakers (CBs) to implement protective functions. The CBs may communicate with various other supervisory devices such as automation systems, monitoring systems, supervisory (SCADA) systems and other intelligent electronic devices (IEDs).

As used herein, an IED may refer to any microprocessor (and/or FPGA)-based device that monitors, controls, automates, and/or protects monitored equipment within an electric power system. Such devices may include, for example, remote terminal units, differential relays, transformer relays, distance relays, directional relays, feeder relays, overcurrent relays, voltage regulator controls, voltage relays, breaker failure relays, generator relays, motor relays, automation controllers, bay controllers, meters, recloser controls, communications processors, computing platforms, programmable logic controllers (PLCs), programmable automation controllers, input and output modules, and the like. The term IED may be used to describe an individual IED or a system comprising multiple IEDs.

The embodiments of the disclosure will be best understood by reference to the drawings. It will be readily understood that the components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor do the steps need to be executed only once, unless otherwise specified.

In some cases, well-known features, structures, or operations are not shown or described in detail. Furthermore, the described features, structures, or operations may be combined in any suitable manner in one or more embodiments. It will also be readily understood that the components of the embodiments, as generally described and illustrated in the figures herein, could be arranged and designed in a wide variety of different configurations. For example, throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment.

Several aspects of the embodiments disclosed herein may be implemented as software modules or components. As used herein, a software module or component may include any type of computer instruction or computer-executable code located within a memory device that is operable in conjunction with appropriate hardware to implement the programmed instructions. A software module or component may, for instance, comprise one or more physical or logical blocks of computer instructions, which may be organized as a routine, program, object, component, data structure, etc., that performs one or more tasks or implements particular abstract data types.

In certain embodiments, a particular software module or component may comprise disparate instructions stored in different locations of a memory device, which together implement the described functionality of the module. Indeed, a module or component may comprise a single instruction or many instructions, and may be distributed over several different code segments, among different programs, and across several memory devices. Some embodiments may be practiced in a distributed computing environment where tasks are performed by a remote processing device linked through a communications network. In a distributed computing environment, software modules or components may be located in local and/or remote memory storage devices. In addition, data being tied or rendered together in a database record may be resident in the same memory device, or across several memory devices, and may be linked together in fields of a record in a database across a network.

Embodiments may be provided as a computer program product including a non-transitory machine-readable medium having stored thereon instructions that may be used to program a computer or other electronic device to perform processes described herein. The non-transitory machine-readable medium may include, but is not limited to, hard drives, floppy diskettes, optical disks, CD-ROMs, DVD-ROMs, ROMs, RAMs, EPROMs, EEPROMs, magnetic or optical cards, solid-state memory devices, or other types of media/machine-readable media suitable for storing electronic instructions. In some embodiments, the computer or another electronic device may include a processing device such as a microprocessor, microcontroller, logic circuitry, or the like. The processing device may further include one or more special purpose processing devices such as an application specific interface circuit (ASIC), PAL, PLA, PLD, field programmable gate array (FPGA), or any other customizable or programmable device.

Electric power delivery systems include equipment, such as generators, power lines, and transformers, to provide electrical energy from sources to loads. Transformers may be used in power systems to step-up or step-down voltages to suitable levels for power lines, buses, loads, or generators. Various IEDs may be used in monitoring, control, and protection of the power delivery system. IEDs may obtain voltage measurements and/or current measurements and send signals to control devices on the power system. For example, transformer relays may obtain voltage measurements of windings of a transformer and disconnect the transformer based on the voltage measurements to protect the transformer or to improve operating conditions of the power system.

Accordingly, IEDs may have a variety of applications and for each application, it may be desirable to have a unique combination of sensors coupled to an IED. According to embodiments of the present disclosure, IEDs may include inputs that are each configured to couple to multiple sensor types (e.g., universal inputs with regard to multiple sensor types). For example, IED inputs according to embodiments of the present disclosure may be configured to be coupled with voltage sensors (e.g., low-power voltage transformers), current sensors that interface with voltage dividers (e.g., low-power current transformers), and current sensors that interface with integrators (e.g., Rogowski coils). In view of this, an IED with such universal inputs may require fewer input ports while maintaining significant flexibility in suitable applications.

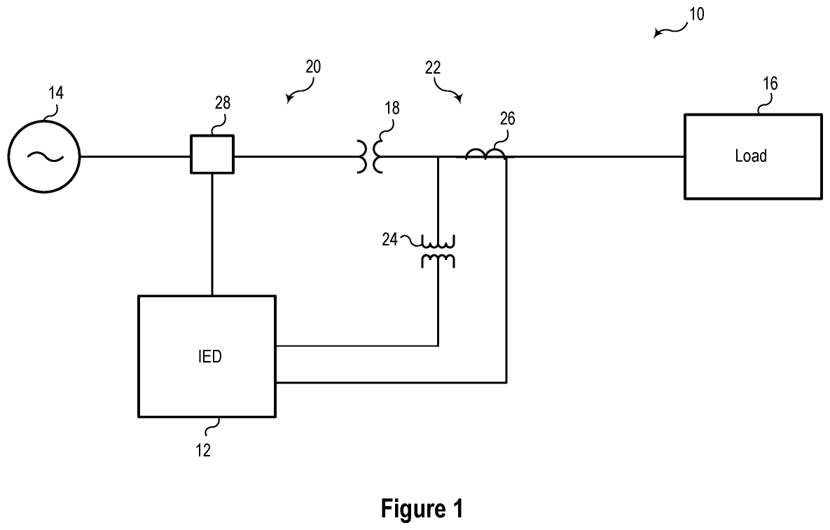

FIG. 1 is a one-line diagram of a power system 10 that includes an IED 12 with inputs configured to be coupled with multiple types of sensors according to an embodiment of the present disclosure. The power system 10 may include a power source 14 that provides power to a load 16. The power system 10 may include a transformer 18, such as a step-up or step-down transformer, that communicatively connects a primary side 20 and a secondary side 22. Voltages on the primary side 20 of the transformer 18 may produce a varying magnetic flux that induces a voltage on the secondary side 22 to allow electrical energy to be transformed to an appropriate level to power the load 16. Although illustrated in a single-line form for purposes of simplicity, the power system 10 may be a multi-phase system, such as a three-phase electric power delivery system. Further, while the power source 14, the load 16, and the transformer 18 are illustrated, any suitable number of power sources, loads, buses, transformers may be used in different power systems.

A component of the power system 10, such as the transformer 18, may be monitored by the IED 12. The IED 12 may obtain electric power system information using a voltage sensor 24 (e.g., a low-power voltage transformer (LPVT)) and/or a current sensor 26 (e.g., a low-power current transformer (LPCT) and/or a Rogowski coil). The IED 12 may detect fault events in the power system 10 (e.g., faults of the transformer 18) using voltage signals of the voltage sensor 24 and/or current signals of the current sensor 26.

In the event a fault is detected in the power system 10, the IED 12 may send a signal to a circuit breaker (CB) 28 to open the CB 28, thereby disconnecting one or more components of the power system 10 (e.g., the transformer 18) from the power source 14.

The system 10 portrayed in the one-line diagram in FIG. 1 provides an example of how an IED 12 may be utilized in a particular power system application, however, it will be understood that the IED 12 may be utilized in a variety of additional power system applications.

Voltage sensor 24 and/or current sensor 26 may interface with IED 12 using an RJ-45 connection. In some embodiments, the interface between IED 12, voltage sensor 24, and current sensor 26 may conform to the IEC 61869 standard. Disclosed herein are various embodiments in which a single interface may be used to interface with multiple types of sensors. For example, such an interface may be used to connect (1) a Rogowski coil, requiring an integrator, (2) a low-power CT (LPCT), or (3) a low power VT (LPVT).

IEC 61869 provides a specified pin-out for each sensor type. Accordingly, various embodiments consistent with the present disclosure may rely on the pin-out for each sensor type to connect various sensors. The outputs of these sensors, depending on the sensor type, may go through either a voltage divider or an integrator. This voltage divider may be tuned so that the input impedance requirements of IEC 61869 are met regardless of which sensor is connected to the input.

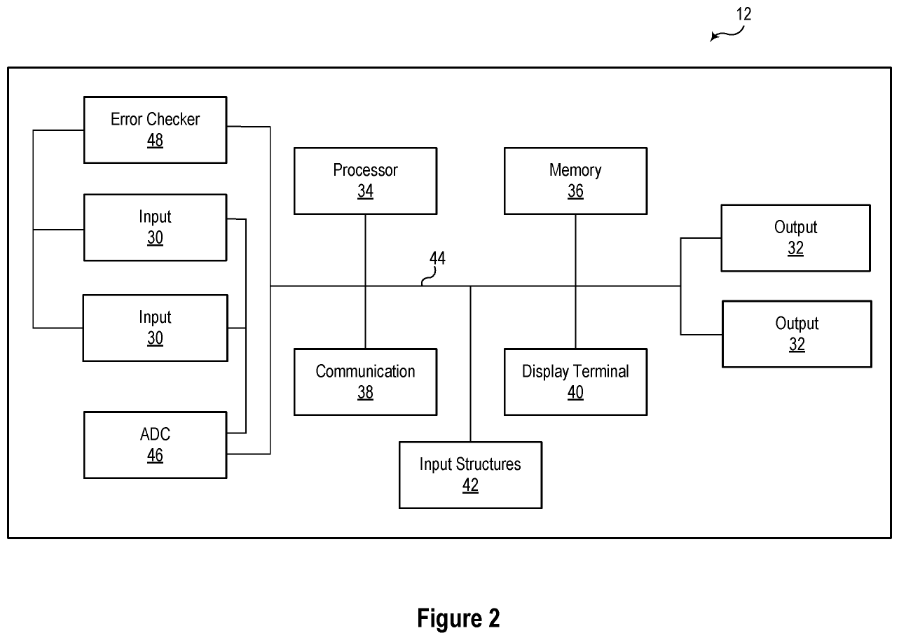

FIG. 2 is a block diagram of the IED 12 according to an embodiment of the present disclosure. The IED 12 may include inputs 30 to allow the IED 12 to receive signals of electrical conditions (e.g., voltage and current) from voltage sensors and/or current sensors. The IED 12 may communicate with external devices, such as CBs, via outputs 32 (e.g., to allow the IED 12 to send a signal to the CB 28 of FIG. 1 to open or close the CB 28). While two inputs 30 and two outputs 32 are shown, an IED 12 according to embodiments of the present disclosure may include any number of inputs 30 and any number of outputs 32.

The IED 12 may further include one or more processors 34, a computer-readable medium (e.g., memory 36), a communication interface 38, a display terminal 40, and input structures 42 communicatively coupled to each other via one or more communication buses 44. The processor 34 may be embodied as a microprocessor, a general-purpose integrated circuit, an application specific integrated circuit (ASIC), a field programmable gate array (FPGA), and/or another programmable logic device. It should be noted that the processor 34 and other related items in FIG. 2 (e.g., the memory 36) may be generally referred to herein as “processing circuitry.” Furthermore, the processing circuitry may be a single contained processing module or may be incorporated wholly or partially within any of the other elements within the IED 12. It should be noted that FIG. 2 is merely one example of a particular implementation and is intended to illustrate the types of components that may be present in the IED 12.

The processor 34 may be operably coupled with the memory 36 to perform various algorithms. Memory 36 may comprise volatile memory, such as random access memory (RAM), and non-volatile memory. Programs or instructions executed by the processor 34 may be stored in any suitable article of manufacture that includes one or more tangible, computer-readable media at least collectively storing the instructions or routines, such as volatile or non-volatile memory.

In some embodiments, the IED 12 may include a communication interface 38, such as a fiber optic transceiver, to communicate with other IEDs. Further, the display terminal 40 and input structures 42 (e.g., Universal-Serial-Bus (USB) ports, buttons, touchscreens, etc.) may allow operators to review events, change settings, etc.

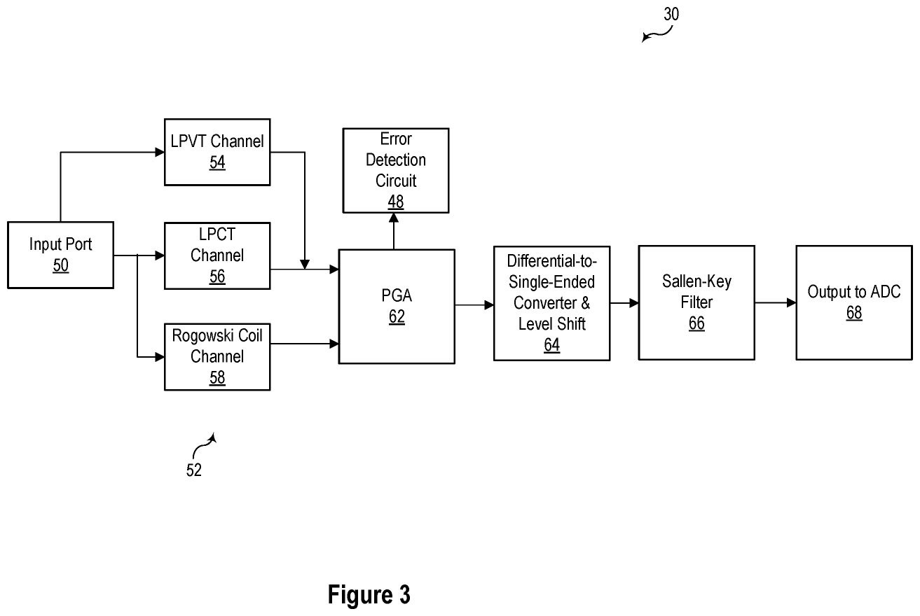

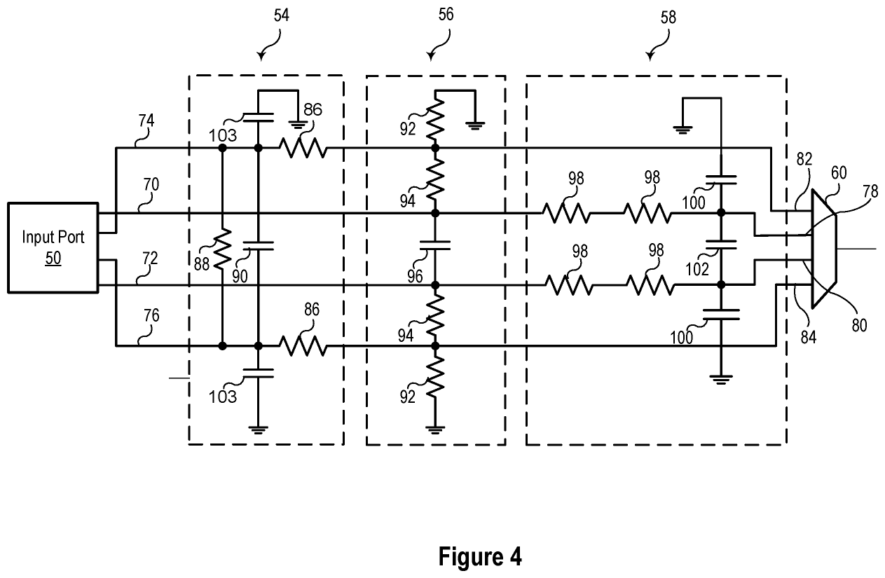

Each input 30 of the IED 12 may include input circuitry that allows the input 30 to be coupled to one of multiple sensor types and to output a signal to an analog-to-digital converter 46 and an error detection circuit 48, as will be described in further detail with reference to FIGS. 3 and 4 below.

FIG. 3 illustrates an input 30 for the IED 12 of FIG. 1 according to an embodiment of the present disclosure. The input 30 may include an input port 50 connected to input circuitry 52 for connecting the IED 12 to a sensor. As used herein, the input port 50 may include ports, connectors, pins, terminals, and the like, used to connect the IED 12 to other devices. For example, the input port 50 may be a RJ-45 jack for connecting to a sensor via an RJ-45 cable. The input circuitry 52 of the input 30 of FIG. 2 may include a plurality of channels, each channel configured for signal processing for a specific type of sensor. For example, the input circuitry 52 may include a low-power voltage transformer (LPVT) channel 54, a low-power current transformer (LPCT) channel 56, and a Rogowski coil channel 58. The channels 54, 56, 58 may be coupled to an inlet of a multiplexer 60 (see FIG. 4) which may direct the appropriate channel to a programmable gain amplifier (PGA) 62.

Electrical contacts (e.g., RJ-45 input pins) may be used and/or a configuration selected by a user to inform the IED 12 about the type of sensor that is connected to the input 30. After the type of sensor is identified, the multiplexer 60 (e.g., a 2:1 multiplexer) may dictate the path taken by the signal. The signal may then go through the PGA 62, which may amplify the signal based on the sensor characteristics. The gain applied by the PGA 62 may vary based on the type of sensor that is connected to the input port 50. In some embodiments, an operator may input the sensor characteristics into the IED 12. In additional embodiments, the sensor characteristics may be automatically detected by the IED 12.

Accordingly, methods of connecting a power system sensor to an IED according to embodiments of the present disclosure may include connecting a power system sensor to an input port of the IED and determining from a variety of power system sensor types which type of power system sensor is connected to the input port. The methods may additionally include receiving signals from the power system sensor with input circuitry and applying signal processing with the input circuitry to the received signal based on the determined power system sensor type.

Additionally, the PGA 62 may be connected to an amplifier circuit and an active or passive circuit. In the illustrated embodiment, it is connected to a differential-to-single-ended converter and level shift 64 (e.g., a differential amplifier circuit with a single output that may apply a level shift to the signal) and a Sallen-Key filter 66 may be applied to the signal prior to sending the signal to an output 68 to the ADC 46 of FIG. 2. Additionally, a signal may be sent from a digital controller of the PGA 62 to an error detection circuit 48 to monitor the signal to determine if the correct amplification has been applied by the PGA 62 to the signal and/or whether the correct channel 54, 56, 58 is being selected by the multiplexer 60.

The error detection circuit 48 may function as an error-checking mechanism that uses error flags and readback from the PGA 62 to ensure that the gains and multiplexer 60 selections are programmed correctly. The error flag from the PGA 62 may connect to digital logic gates that inform the IED 12 if the expected gain and multiplexer 60 selection has not been programmed correctly. When the IED 12 is informed of this, a second attempt may be performed to program the PGA 62, power to the PGA 62 may be cycled, and a third attempt may be performed to program the PGA 62. In some embodiments, if after three attempts the PGA 62 is still not programmed correctly, an error message may be displayed to an operator prompting them to seek additional assistance.

The error detection circuit 48 may provide improved reliability as it may ensure that the PGA 62 is always programmed correctly (e.g., per the operator's instructions) for the sensor type. This may prevent false tripping and incorrect metering, thereby increasing the robustness of the system.

A detected sensor type, and/or a sensor type selected and input by an operator, may determine how a scaling factor is calculated that dictates the gain of the PGA 62 to ensure that the system is not over-sensitive or under-sensitive.

FIG. 4 illustrates a schematic of a portion of the input circuitry 52 of FIG. 3 for an input 30 according to an embodiment of the present disclosure. As shown, the input port 50 may be coupled to the LPVT channel 54, the LPCT channel 56, and the Rogowski coil channel 58. The LPVT channel 54, the LPCT channel 56, and the Rogowski coil channel 58 may be coupled to input lines of a multiplexer 60. The Rogowski coil channel 58 may be coupled to a first input of the multiplexer 60 and the LPVT channel 54 and the LPCT channel 56 may be coupled to a second input of the multiplexer 60. The multiplexer 60 may be configured to selectively connect either the Rogowski coil channel 58 or the LPVT channel 54 and the LPCT channel 56 to the circuitry of the PGA 62 of FIG. 3.

As shown, the circuitry for the LPVT channel 54, the LPCT channel 56, and the Rogowski coil channel 58 may include four lines 70, 72, 74, 76 extending from the input port 50 to the multiplexer 60. A first line 70 may extend from the input port 50 (e.g., from a first pin of an RJ-45 jack) to a positive first input 78 of the multiplexer. A second line 72 may extend from the input port 50 (e.g., from a second pin of an RJ-45 jack) to a negative first input 80 of the multiplexer 60. A third line 74 may extend from the input port 50 (e.g., from a seventh pin of an RJ-45 jack) to a positive second input 82 of the multiplexer 60. A fourth line 76 may extend from the input port 50 (e.g., from an eighth pin of an RJ-45 jack) to a negative second input 84 of the multiplexer 60.

Looking now to the circuitry of the LPVT channel 54, the third line 74 and fourth line 76 may each include one or more resistors 86 (e.g., a 1.8 M Ohm resistor), respectively. A resistor 88 may span between the third line 74 and fourth line 76 (e.g., a 4 M Ohm resistor may connect the third line 74 and fourth line 76) at a location between the input port 50 and the resistors 86, which may control input impedance. A capacitor 90 may also span between the third line 74 and fourth line 76 (e.g., a 50 p Farad capacitor) at a location between the input port 50 and the resistors 86. Accordingly, the LPVT channel 54 may function as a voltage divider circuit.

Looking now to the circuitry of the LPCT channel 56, the third line 74 and fourth line 76 may each be connected to ground, respectively, via a resistor 92 (e.g., a 200 k Ohm resistor) at a location between the resistors 86 and the multiplexer 60. The first line 70 and the third line 74 may be connected via a resistor 94 (e.g., a 1.8 M Ohm resistor) at a location between the circuitry of the LPVT channel 54 and the circuitry of the Rogowski coil channel 58. Likewise, the second line 72 and the fourth line 76 may be connected via a resistor 94 (e.g., a 1.8 M Ohm resistor) at a location between the circuitry of the LPVT channel 54 and the circuitry of the Rogowski coil channel 58. The third line 74 and the fourth line 76 may each be coupled to ground, respectively, via a capacitor 103 (e.g., a 0.1μ Farad capacitor) at a location between the resistor 88 and the resistors 86. Finally, a capacitor 96 (e.g., a 50μ Farad capacitor) may be connected to the first line 70 and the second line 72 at a location between the circuitry of the LPVT channel 54 and the circuitry of the Rogowski coil channel 58. Accordingly, the LPCT channel 56 may comprise a voltage divider circuit.

Looking now to the circuitry of the Rogowski coil channel 58, the first line 70 and the second line 72 may each include one or more resistors 98 (e.g., a pair of 1 M Ohm resistors) located between the circuitry of the LPCT channel 56 and the multiplexer 60. The first line 70 and the second line 72 may each be coupled to ground, respectively, via a capacitor 100 (e.g., a 0.1 p Farad capacitor) at a location between the resistors 98 and the multiplexer 60. Additionally, a capacitor 102 (e.g., a 0.1 p Farad capacitor) may be connected to the first line 70 and the second line 72 at a location between the resistors 98 and the multiplexer 60. Accordingly, the Rogowski coil channel 58 may function as a passive integrator circuit. In view of the foregoing, the inputs 30 of the IED 12 may support fully differential or single-ended inputs. In some embodiments, the capacitors 100 and 102 may form a passive integrator circuit to integrate the signal of the Rogowski coil. In other embodiments, these capacitors may serve only for common-mode rejection and digital integration in the IED may be employed.

Accordingly, an IED according to embodiments of the present disclosure may include an analog-to-digital converter, an input port, and input circuitry connecting the input port to the analog-to-digital converter. The input circuitry may be configured to receive electrical signals from a plurality of types of power system sensors via the input port and apply appropriate signal processing before sending the electrical signals to the analog-to-digital converter.

While specific embodiments and applications of the disclosure have been illustrated and described, it is to be understood that the disclosure is not limited to the precise configurations and components disclosed herein. Accordingly, many changes may be made to the details of the above-described embodiments without departing from the underlying principles of this disclosure. The scope of the present invention should, therefore, be determined only by the following claims.

What is claimed is:

1. A configurable multi-sensor analog input, comprising:
an input port comprising a plurality of input pins and configured to receive electrical signals from at least one of a plurality of types of power system sensors;
a plurality of input channels, each of the plurality of input channels coupled to a subset of the input pins, wherein the subset of input pins in electrical communication with at least one of the plurality of types of power system sensors is configured to selectively activate one of the plurality of channels; and
a multiplexer in electrical communication with the plurality of input channels and configured to select an output based on the subset of input pins in electrical communication with the power system sensor.

2. The configurable multi-sensor analog input of claim 1, wherein the at least one of the plurality of types of power system sensors comprises a low-power voltage transformer, a low-power current transformer, and a Rogowski coil.

3. The configurable multi-sensor analog input of claim 1, wherein the plurality of input channels comprises a low-power voltage transformer channel, a low-power current transformer channel, and a Rogowski channel.

4. The configurable multi-sensor analog input of claim 3, wherein the Rogowski channel comprises an integrator circuit.

5. The configurable multi-sensor analog input of claim 3, wherein the low-power voltage transformer channel and the low-power current transformer channel are coupled to the same plurality of input pins of the input port.

6. The configurable multi-sensor analog input of claim 1, wherein the input port complies with International Electrotechnical Commission (“IEC”) standard 61869.

7. The configurable multi-sensor analog input of claim 5, wherein an input impedance of each of the plurality of input channels complies with IEC standard 61869.

8. The configurable multi-sensor analog input of claim 1, further comprising a programmable gain amplifier (“PGA”) to amplify a signal provided to an output of the multiplexer.

9. The configurable multi-sensor analog input of claim 8, further comprising an error detection circuit configured to monitor the output and determine whether the PGA has applied a correct amplification.

10. The configurable multi-sensor analog input of claim 1, wherein the input port is comprised by an intelligent electronic device configured for use in an electric power system.

11. A method of connecting at least one of a plurality of types of power system sensors, the method comprising:
providing an input port comprising a plurality of input pins and configured to receive electrical signals from at least one of the plurality of types of power system sensors;
coupling a plurality of input channels, each of the plurality of input channels coupled to a subset of the input pins, wherein the subset of input pins in electrical communication with one of the plurality of types of power system sensors is configured to selectively activate one of the plurality of channels; and
selecting an output of a multiplexer in electrical communication with the plurality of input channels based on the subset of input pins in electrical communication with a power system sensor.

12. The method of claim 11, wherein the at least one of the plurality of types of power system sensors comprises a low-power voltage transformer, a low-power current transformer, and a Rogowski coil.

13. The method of claim 11, wherein the plurality of input channels comprises a low-power voltage transformer channel, a low-power current transformer channel, and a Rogowski channel.

14. The method of claim 13, wherein the Rogowski channel comprises an integrator circuit.

15. The method of claim 13, wherein the low-power voltage transformer channel and the low-power current transformer channel are coupled to the same plurality of input pins of the input port.

16. The method of claim 11, wherein the input port complies with International Electrotechnical Commission (“IEC”) standard 61869.

17. The method of claim 11, wherein an input impedance of each of the plurality of input channels complies with IEC standard 61869.

18. The method of claim 11, further comprising amplifying a signal provided to an output of the multiplexer using a programmable gain amplifier (“PGA”).

19. The method of claim 18, further comprising monitoring the output and determining whether the PGA has applied a correct amplification.

20. The method of claim 11, wherein the input port is comprised by an intelligent electronic device configured for use in an electric power system.
